(19) United States
(12) Patent Application Publication
(10) Pub. No.: US 2010/0254094 A1
(43) Pub. Date: Oct. 7, 2010

(54) High-Frequency Wiring Board and High-Frequency Module That Uses the High-Frequency Wiring Board

(76) Inventor: Risato Ohhira, Tokyo (JP)

Correspondence Address: Mr. Jackson Chen, 6535 N. STATE HWY 161, IRVING, TX, 75039, US

(21) Appl. No.: 12/739,847

(22) PCT Filed: Sep. 10, 2008
(86) PCT No.: PCT/JP2008/066347

§ 371 Date: Apr. 26, 2010

(30) Foreign Application Priority Data
Oct. 25, 2007 (JP) 2007-277686

(51) Int. Cl. H05K 7/00; H01P 5/12

(52) U.S. Cl. 361/728; 333/136

(57) ABSTRACT

The high-frequency wiring board of the present invention is a wiring board that includes first coplanar lines and second coplanar lines formed on a different layer than the first coplanar lines; the first coplanar lines and second coplanar lines being connected at the line ends of each. The first coplanar lines are provided with a first signal line (10) and a first planar ground pattern (30a) formed on the same wiring layer as the first signal line (10). The second coplanar lines are provided with second signal line (11) formed on a wiring layer that differs from that of the first signal line (10), a second planar ground pattern 32 formed on the same wiring layer as the second signal line, and a first ground pattern (30b) formed on the same wiring layer as the first coplanar lines. The end of the first planar ground pattern (30a) and the end of the first ground pattern (30b) are connected and thus unified. In this high-frequency wiring board, the second planar ground pattern (32) is separated from the connection portion at the end of the first planar ground pattern (30a) in the direction in which the second coplanar lines extend from the vicinity of the connection portion of the first signal line and the second signal line.

### TECHNICAL FIELD

The present invention relates to a high-frequency wiring board on which high-frequency transmission lines are formed, and more particularly to the interconnection of high-frequency transmission lines formed on different layers of a wiring board.

### BACKGROUND ART

In high-frequency transmission lines used in, for example, packages for high-frequency semiconductor elements and wiring boards for mounting circuit elements, obverse-surface signal lines formed on the obverse surface of a dielectric substrate and intermediate-layer signal lines formed in the interior of the dielectric substrate are frequently interconnected by the relations of mounting positions of electronic components.

Microstrip lines or coplanar lines are representative of obverse-surface signal lines that are formed on the obverse surface of a dielectric substrate, and strip lines and coplanar lines are representatively used as intermediate-layer signal lines that are formed within a dielectric substrate. The interconnections between obverse-surface signal line and intermediate-layer signal lines are typically realized by vias or through-holes having electrical conductivity.

For example, the high-frequency wiring board described in JP-A-2003-133472 (hereinbelow referred to as Patent Document 1) includes high-frequency transmission lines as shown in FIGS. 1A-1D. FIG. 1A is an overall perspective view of the high-frequency wiring board, FIG. 1B is a perspective view of the second dielectric layer portion of the high-frequency wiring board, and FIG. 1C is an upper plan view of the rear-surface conductive pattern of the high-frequency wiring board. FIG. 1D shows a sectional view taken along line X-X in the direction of signal transmission of the high-frequency wiring board shown in FIG. 1A.

The high-frequency wiring board shown in these figures is composed of dielectric substrate 20 made up of two dielectric layers 20a and 20b, and high-frequency transmission lines are formed on different layers.

The first high-frequency transmission lines are made up from: first signal lines 10 formed on the upper surface of first dielectric layer 20a that is the obverse surface of dielectric substrate 20, first ground pattern 30 arranged on the same surface as signal lines 10 and surrounding signal lines 10, and second ground pattern 32 formed on the upper surface of second dielectric layer 20b. In contrast, second high-frequency transmission lines are made up from: above-described first ground pattern 30, third ground pattern 31 formed on the lower surface of second dielectric layer 20b that is the rear surface of dielectric substrate 20, second signal line 11 formed on the upper surface of second dielectric layer 20b and arranged between first ground pattern 30 and third ground pattern 31, and second ground pattern 32 arranged around this signal line 11 and on the same surface.

The end of first signal line 10 of the first high-frequency transmission lines and the end of second signal line 11 of the second high-frequency transmission line are connected by via 40 having electrical conductivity. In addition, first ground pattern 30, second ground pattern 32, and third ground pattern 31 are electrically connected by a plurality of conductive vias 41 arranged along the signal transmission direction of first signal lines 10 and second signal line 11.

However, when different types of line constructions formed on different layers are connected together, as with first high-frequency transmission lines and second high-frequency transmission lines, mismatching tends to occur in the vicinity of the connection portions, and as a result, signal reflection tends to occur increasingly as the frequency increases.

Methods have therefore been proposed as in, for example, JP-A-2004-320109 (hereinbelow referred to as Patent Document 2) for limiting impedance mismatching and thus decreasing reflection by changing the end width of signal lines that correspond to first signal lines 10 that make up the above-described first high-frequency transmission lines, i.e., changing the width in the vicinity of connection portions with conductive vias 40.

Patent Document 1: JP-A-2003-133472 (FIG. 5)

Patent Document 2: JP-A-2004-320109 (FIG. 1, paragraph 0095)

As described hereinabove, when different types of signal line constructions, in which signal lines are formed on different layers in the configuration shown in FIGS. 1A-1D are connected, changing the signal line width in the vicinities of conductive vias that interconnect signal lines results in an improvement of the reflection characteristics. However, it was found that the related art could not provide a solution to the problem in which the reflection characteristics deteriorate as the transmission signal progresses from low frequencies to higher frequencies.

The reasons for this problem are next explained with reference to FIG. 1D.

In the configuration shown by FIGS. 1A-1D, when a signal is transmitted from the first high-frequency transmission lines to the second high-frequency transmission lines, the signal-line side current of the high-frequency current that is propagated over first ground pattern 30 and first signal lines 10 of the first high-frequency transmission lines flows along second signal line 11 of the second high-frequency transmission lines. However, the current flow on the ground pattern side flows not only through second ground pattern 32 of the second high-frequency transmission lines, but is propagated by two paths to first ground pattern 30. In other words, as shown in FIG. 1D, the current is propagated on path A that passes by only first ground pattern 30 and on path B that passes successively from first ground pattern 30 along the signal transmission direction to conductive via 41a, second ground pattern 32, and then the succeeding conductive via 41b before again returning to first ground pattern 30.

If a case is here considered in which the two physical path lengths are L1 and L2, the path length difference L1−L2 is ΔL, the wavelength of signal transmission in a vacuum is λ₀, the wave number of each path is the same at k, and the effective relative dielectric constants on each path are the same at ∈ᵣ, the phase difference between the two paths A and B is represented as shown in the following Formula (1):

$$\begin{matrix}[ Formula 1 ] & \\ \begin{matrix}k \times L 1 - k \times L 2 = k \times Δ L \\ = ( \frac{2 π }{λ 0 / \sqrt{ɛ}} ) \times Δ L \\ = ( 2 π \times \sqrt{ɛ} ) \times ( \frac{Δ L}{λ 0} )\end{matrix} & ( 1 )\end{matrix}$$

and is proportional to ΔL/λ₀.

As a result, even if the physical path length difference ΔL is fixed, interpath phase difference tends to increase and phase interference more readily occurs as the transmission signal reaches higher frequencies, i.e., with shorter wavelengths λ₀.

Essentially, it was found that even when the method taught in Patent Document 2 is adopted, in the configuration shown in FIGS. 1A-1D, the potential for improving the reflection characteristics diminishes as the signal transmission from the first high-frequency transmission lines to the second high-frequency transmission lines reaches higher frequencies.

### DISCLOSURE OF THE INVENTION

It is an object of the present invention to provide a high-frequency signal line connection construction for solving the above-described problems. One example of this object is to provide a construction that enables an improvement of reflection characteristics from a low-frequency region to a high-frequency region in a high-frequency wiring board equipped with different types of lines that are formed on different layers and that are interconnected.

The high-frequency wiring board according to one mode of the present invention is a wiring board having first coplanar lines and second coplanar lines formed on a different layer from the first coplanar lines, the first coplanar lines and second coplanar lines being connected at the end of each. The first coplanar lines are provided with a first signal line and a first planar ground pattern formed on the same wiring layer as the first signal line. The second coplanar lines are provided with a second signal line formed on a wiring layer that differs from the first signal line, a second planar ground pattern formed on the same wiring layer as the second signal line, and a first ground pattern formed on the same wiring layer as the first coplanar lines. The end of the first planar ground pattern and the end of the first ground pattern are connected and unified. The present invention is characterized in that, in this high-frequency wiring board, the second planar ground pattern is separated from the connection portion at the end of the first planar ground pattern in the direction in which the second coplanar lines extend from the vicinity of the connection portion between the ends of first signal line and the second signal line.

### BRIEF DESCRIPTION OF THE DRAWINGS

FIG. 1A is an overall perspective view of the high-frequency wiring board disclosed in Patent Document 1;

FIG. 1B is a perspective view of a portion of the second dielectric layer of the high-frequency wiring board of FIG. 1A;

FIG. 1C is an upper view of the third layer wiring of the high-frequency wiring board of FIG. 1A;

FIG. 1D is a sectional view taken along line X-X in the direction of signal transmission of the high-frequency wiring board shown in FIG. 1A;

FIG. 2A is a plan view showing the first wiring layer of the high-frequency wiring board of the first embodiment;

FIG. 2B is a plan view showing the second wiring layer of the high-frequency wiring board of the first embodiment;

FIG. 2C is a plan view showing the third wiring layer of the high-frequency wiring board of the first embodiment;

FIG. 2D is a sectional view of the high-frequency wiring board taken along line A-A′ of FIG. 2A;

FIG. 2E is a sectional view of the high-frequency wiring board taken along line B-B′ of FIG. 2A;

FIG. 2F is a sectional view of the high-frequency wiring board taken along line C-C′ of FIG. 2A;

FIG. 2G is a sectional view of the high-frequency wiring board taken along line D-D′ of FIG. 2A;

FIG. 2H is a sectional view of the high-frequency wiring board taken along line E-E′ of FIG. 2A;

FIG. 3 gives a schematic representation of the high-frequency current path on the signal-line side and the high-frequency current path on the ground-pattern side based on the results of electromagnetic field analysis of the high-frequency transmission line construction of the first embodiment;

FIG. 4 is an explanatory view of the spacing range of conductive vias arranged along the direction of signal transmission in the high-frequency transmission line construction of the first embodiment;

FIG. 5 shows the results of electromagnetic field analysis in which a comparison of the input reflection characteristics of a comparative example and the first embodiment was carried out;

FIG. 6 shows the results of electromagnetic field analysis in which comparison of the input reflection characteristics in the first embodiment was carried out while changing the separation width;

FIG. 7A is a plan view showing the first wiring layer of the high-frequency wiring board of the second embodiment;

FIG. 7B is a plan view showing the second wiring layer of the high-frequency wiring board of the second embodiment;

FIG. 7C is a plan view showing the second wiring layer of the high-frequency wiring board of the second embodiment;

FIG. 7D is a sectional view of the high-frequency wiring board taken along line A-A′ of FIG. 7A;

FIG. 7E is a sectional view of the high-frequency wiring board taken along line B-B′ of FIG. 7A;

FIG. 7F is a sectional view of the high-frequency wiring board taken along line C-C′ of FIG. 7A;

FIG. 7G is a sectional view of the high-frequency wiring board taken along line D-D′ of FIG. 7A;

FIG. 7H is a sectional view of the high-frequency wiring board taken along line E-E′ of FIG. 7A;

FIG. 8 is a schematic representation of the high-frequency current path on the signal-line side and the high-frequency current path on the ground-pattern side based on the results of electromagnetic field analysis of the high-frequency transmission line construction of the second embodiment;

FIG. 9 shows the results of electromagnetic field analysis in which a comparison of the input reflection characteristics of a comparative example and the second embodiment was carried out;

FIG. 10 shows the results of electromagnetic field analysis in which comparison of the input reflection characteristics in the second embodiment was carried out while changing the separation width;

FIG. 11 is a sectional view taken along a signal line of an example of a module that uses the high-frequency wiring board of the present invention; and

FIG. 12 is a sectional view taken along a signal line of an example of a module that uses the high-frequency wiring board of the present invention.

### BEST MODE FOR CARRYING OUT THE INVENTION

The present invention is next described in detail with reference to the accompanying figures.

### First Embodiment

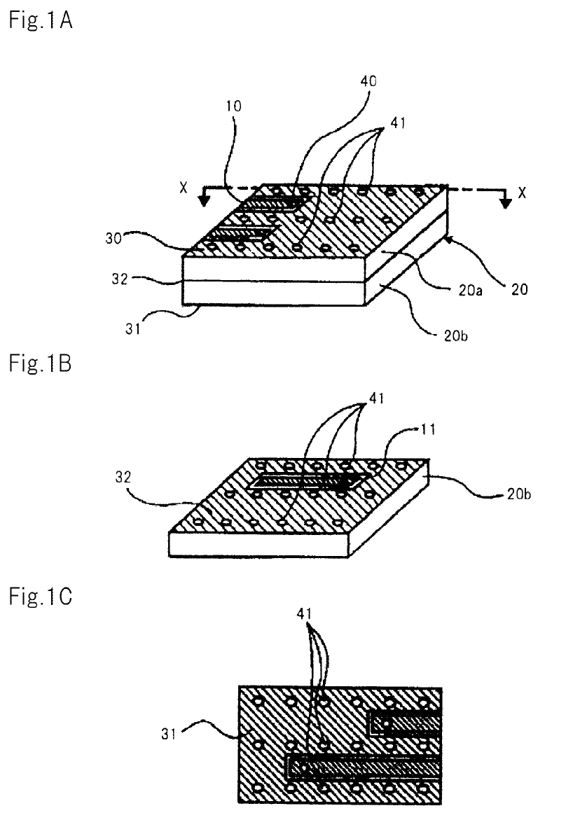

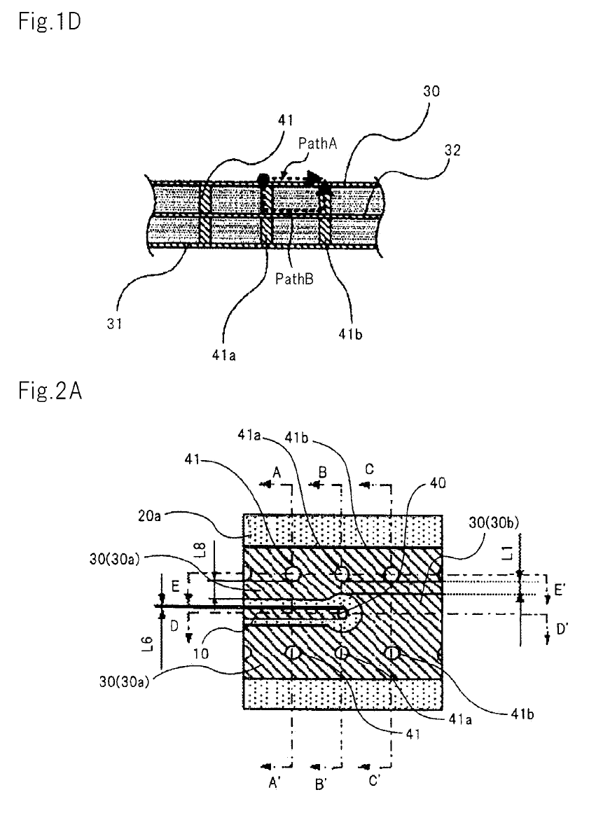

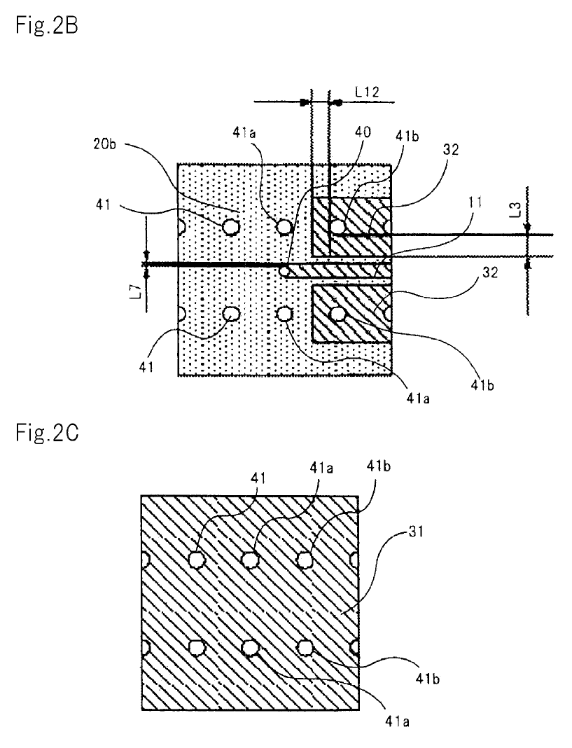

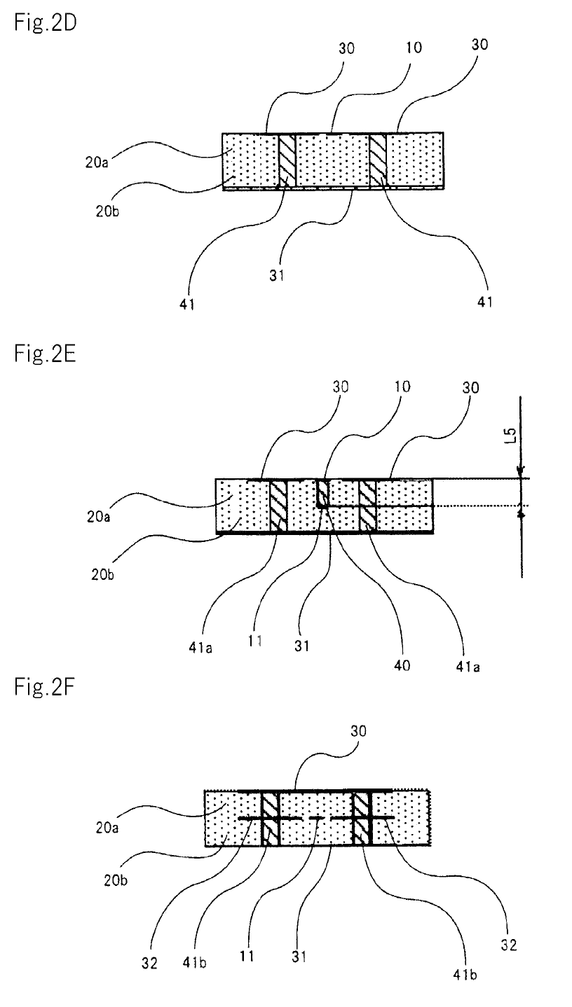

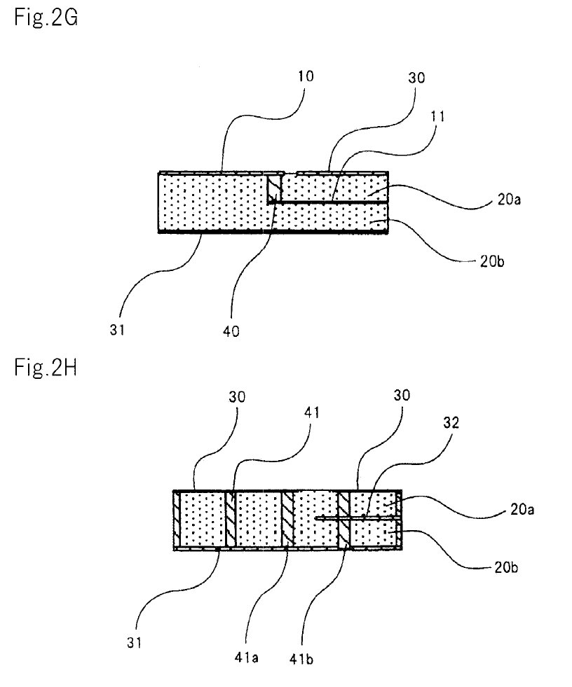

FIGS. 2A-2H show the construction of the high-frequency wiring board according to the first embodiment of the present invention. To state in greater detail, FIG. 2A is a plan view showing the first wiring layer of the high-frequency wiring board of the present embodiment; FIG. 2B is a plan view of the second wiring layer, and FIG. 2C is a plan view of the third wiring layer. FIG. 2D is a sectional view of the board taken along line A-A′ of FIG. 2A, FIG. 2E is a sectional view of the board taken along line B-B′ of FIG. 2A, FIG. 2F is a sectional view of the board taken along line C-C′ of FIG. 2A, FIG. 2G is a sectional view of the board taken along line D-D′ of FIG. 2A, and FIG. 2H is a sectional view of the board taken along line E-E′ of FIG. 2A. In each figure, the same reference numbers are used for functional parts that are the same as constituent elements shown in FIGS. 1A-1D.

The high-frequency wiring board of the present embodiment is composed of dielectric substrate 20 in which two dielectric layers 20a and 20b are stacked. First coplanar lines are formed on the upper surface of first dielectric layer 20a that is the obverse surface (first wiring layer) of dielectric substrate 20 (FIG. 2A). The first coplanar lines are made up from first signal line 10 and planar ground pattern 30a that is formed on both sides of first signal line 10 and on the same layer as first signal line 10. Second coplanar lines are formed on the upper surface of second dielectric layer 20b that is the internal layer (second wiring layer) of dielectric substrate 20 (FIG. 2B). The second coplanar lines are made up from second signal line 11 and planar ground pattern 32 that is formed on both sides of this second signal line 11 and on the same layer as second signal line 11. In addition, each of planar ground patterns 30a and 32 of the first and second coplanar lines, respectively, may be formed on only one of the two side positions that sandwich the respective signal lines.

First signal line 10 of the first coplanar lines and second signal line 11 of the second coplanar lines that are on a wiring layer that differs from that of first signal line 10 are connected at conductive via 40 at the line end of each signal line.

Planar first ground pattern 30b and planar second ground pattern 31 are formed on the first wiring layer and third wiring layer (the reverse surface of dielectric substrate 20) such that the layer on which second signal line 11 is formed is sandwiched from above and below. This second ground pattern 31 extends to areas that are opposite the first coplanar lines and further serves as the lower-layer ground of the first coplanar lines. In addition, first ground pattern 30b is connected with planar ground pattern 30a at the ends in the direction of the first coplanar lines and the two ground patterns are thus unified as ground pattern 30.

Further, planar ground pattern 30a of the first coplanar lines and second ground pattern 31 that doubles as the lower-layer ground of the first coplanar lines are interconnected by a plurality of conductive vias 41 that are arranged at a predetermined spacing along the signal transmission direction of the first coplanar lines.

In addition, first ground pattern 30b that is on the upper layer of the second coplanar lines, planar ground pattern 32 of the second coplanar lines, and second ground pattern 31 are interconnected by a plurality of conductive vias 41 (41b) that are arranged at a predetermined spacing along the signal transmission direction of the second coplanar lines.

On the other hand, of the plurality of conductive vias 41, conductive vias 41a in the vicinity of the connection portion of first signal line 10 and second signal line 11 are separated from planar ground pattern 32 and do not interconnect planar ground pattern 30a of the first coplanar lines and planar ground pattern 32 of the second coplanar lines as in the background art. More specifically, conductive vias 41a in the vicinity of the connection portion of first signal line 10 and second signal line 11 are separated from planar ground pattern 32 of the second coplanar lines by a predetermined width (dielectric width) in the direction of the extension of the second coplanar lines from the vicinity of the connection portion of first signal line 11 and conductive via 40.

In the high-frequency transmission lines of the high-frequency wiring board as described above, conductive vias 41a in the vicinity of the connection portion of first signal line 10 and second signal line 11 is separated from planar ground pattern 32 of the second coplanar lines in the direction in which the second coplanar lines extend from the vicinity of the connection portion of first signal line 10 and conductive via 40. As a result, when a signal is transmitted from the first coplanar lines to the second coplanar lines, the high-frequency current paths that are propagated in the first ground pattern 30b of the upper layer of the second coplanar lines are limited to one. In other words, the high-frequency current path that is propagated in first ground pattern 30b during signal transmission to the second coplanar lines is only the path that passes directly toward first ground pattern 30b from planar ground pattern 30a of the first coplanar lines without passing by way of different layers. In this way, phase interference of the high-frequency current that is propagated in first ground pattern 30b does not occur, and as a result, an improvement can be attained in reflection characteristics that deteriorate with progression from low frequency to high frequency.

This effect is obtained if conductive vias 41a in the vicinity of the connection portion of first signal line 10 and second signal line 11 is separated from planar ground pattern 32 of the second coplanar lines, and the separation portion may therefore be of any form. In other words, the confronting sides of planar ground pattern 32 of the second coplanar lines with respect to conductive vias 41a need not be a straight lines as shown in the figure, and moreover, need not be perpendicular to the signal transmission direction of the first coplanar lines and second coplanar lines.

Additional conditions for further improving the reflection characteristics are next described. However, the following description presupposes a construction in which conductive vias 41a in the vicinity of the connection portion of first signal line 10 and second signal line 11 are separated from planar ground pattern 32 of the second coplanar lines.

As an additional condition for further improving the reflection characteristics in the present embodiment, the degree of separation between conductive vias 41a in the vicinity of the connection portion of first signal line 10 and second signal line 11 and planar ground pattern 32 of the second coplanar lines is prescribed as follows: i.e., the separation width is prescribed to be greater than 0, and moreover, no greater than spacing dx from conductive vias 41a in the vicinity of the connection end of first signal line 10 to next conductive vias 41b in the direction of the signal transmission.

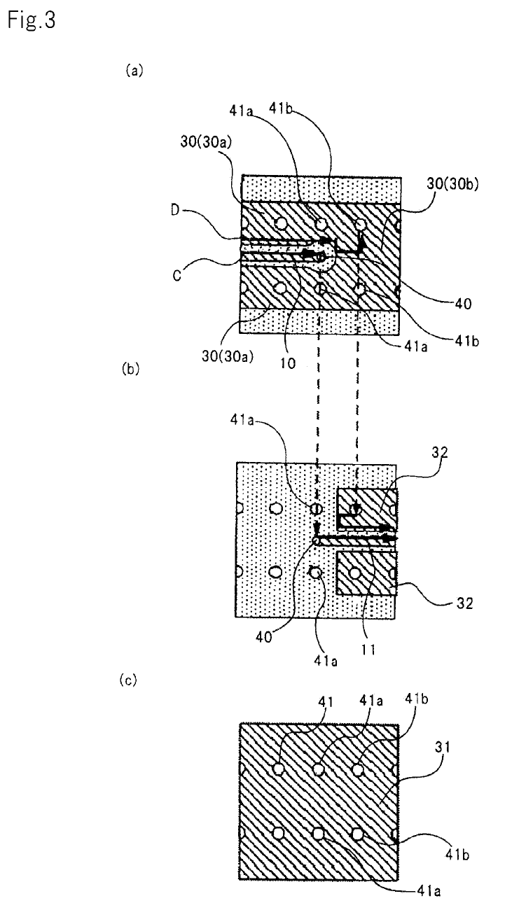

The reason why this condition achieves a further improvement of the reflection characteristics of the present embodiment is next explained using FIG. 3. FIG. 3 gives a schematic representation of signal-line side high-frequency current path C that is propagated through signal lines 10 and 11 and ground-pattern side high-frequency current path D that is propagated through planar ground pattern 32 of the second coplanar lines based on the results of electromagnetic field analysis of the high-frequency transmission line construction of the present embodiment. In these figures, (a), (b) and (c) show states corresponding to FIG. 2A, FIG. 2B, and FIG. 2C; the ground-pattern side high-frequency current path D in the figures shows the state of propagation from planar ground pattern 30a of the first coplanar lines and through planar ground pattern 32 of the second coplanar lines by way of conductive via 41b. As can be seen from this figure, a difference in path length occurs between signal-line side high-frequency current path C that follows the opposing signal lines and ground-pattern side high-frequency current path D that follows the outer peripheries of the opposing ground patterns. Because the distance between conductive via 41b and the outer periphery of planar ground pattern 32 is decreased to the extent that the above-described separation width is increased, the length of ground-pattern side high-frequency current path D in FIG. 3 becomes shorter and the difference in the path length between the signal-line side high-frequency current path C and ground-pattern side high-frequency current path D also becomes shorter. As a result, to the extent that the separation width is increased, i.e., to the extent that the difference in path length between current paths C and D is reduced, the phase difference between signal-line side high-frequency current path C and ground-pattern side high-frequency current path D can be reduced, as can be seen from the above-described Formula (1).

As a result, a further improvement of the reflection characteristics can be achieved by setting the upper limit of the separation width to spacing dx of conductive vias 41 that can provide maximum separation between conductive via 41a and planar ground pattern 32.

Spacing dx is prescribed by the arrangement spacing of, for example, conductive vias 41a and 41b that are formed in the area of the second coplanar lines rather than the first coplanar lines. In addition, the arrangement spacing of conductive vias 41a and 41b formed in the area of the second coplanar lines is a value determined for realizing a desired frequency band in the second coplanar lines.

The method of calculating via spacing dx is next described.

The inventors of the present invention have set the sum of the minimum distance to the conductive via to be closest to any point of planar ground pattern 32 of the second coplanar lines and the dielectric layer thickness to be no greater than a particular predetermined value, and have thus found that increase in impedance deviation on planar ground pattern 32 that accompanies the increase in frequency is suppressed, and as a result, the reflection characteristics of the coplanar transmission lines are improved over a broad band. Based on this concept, a formula that includes formula modifications is shown below specifically as a formula for prescribing via spacing dx.

If: R is the shortest distance to the nearest via periphery from any point on the outer periphery of planar ground pattern 32 in the second coplanar lines, L3 is the shortest distance from the outer periphery of conductive via 41b to the outer periphery of planar ground pattern 32 on the second signal line 11 side, L5 is the thickness of dielectric layer 20a between the wiring layers, ∈₂ is the effective relative dielectric constant of the second coplanar lines, and λ₀ is the wavelength of the transmission signal in a vacuum, then via spacing dx is set such that the following formula is satisfied:

$$\begin{matrix}[ Formula 2 ] & \\ ( \frac{2 π}{λ 0 / \sqrt{{ɛ}_{2}}} ) \times ( R + L 5 ) < \frac{π}{2} , or , R + L 5 < \frac{1}{4} \times \frac{λ 0}{\sqrt{{ɛ}_{2}}} & ( 2 )\end{matrix}$$

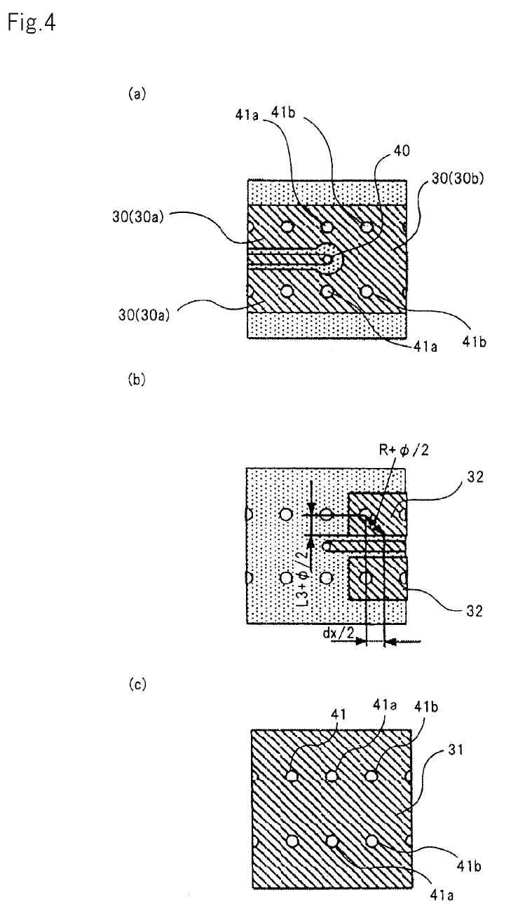

In the present embodiment, assuming the diameter of conductive via 41 is φ, the maximum shortest distance R based on FIG. 4 is represented by:

[Formula 3]

R=\sqrt{(L3+φ/2)²+(dx/2)²}−φ/2 (3)

Based on the above-described Formulas (2) and (3), the formula that via spacing dx must satisfy becomes:

$$\begin{matrix}[ Formula 4 ] & \\ dx < 2 \times \sqrt{{( \frac{1}{4} \times \frac{λ 0}{\sqrt{{ɛ}_{2}}} + φ / 2 - L 5 )}^{2} - {( L 3 + φ / 2 )}^{2}} & ( 4 )\end{matrix}$$

In addition, the above-described separation width can also be prescribed as next described. During signal transmission from the first coplanar lines to the second coplanar lines, conditions are preferable whereby a large shift in difference does not occur in electrical path lengths (difference in electrical length converted by the effective relative dielectric constant) between the high-frequency current that is propagated in ground patterns and the high-frequency current that is propagated through signal lines. Accordingly, the separation width is prescribed to a range by which the phases of high-frequency currents on the ground pattern side and signal line side do not invert at the particular signal wavelength λₒ (the minimum wavelength (maximum frequency) of the desired signal band).

More specifically, as shown in FIGS. 2A, 2B, and 2E, L1 is the shortest distance from the periphery of, among the plurality of conductive vias 41 provided in the first coplanar lines, conductive via 41a that is closest to conductive via 40, to the outer periphery of planar ground pattern 30a on the first signal line 10 side.

L3 is the shortest distance from the periphery of, among the plurality of conductive vias 41 that are provided in the second coplanar lines and excluding conductive vias 41a, conductive via 41b that is closest to conductive via 40, to the outer periphery of planar ground pattern 32 on the second signal line 11 side.

L12 is the shortest distance from the periphery of the above-described conductive via 41b to the outer periphery of planar ground pattern 32 on the first coplanar line side.

L5 is the dielectric layer thickness between first ground pattern 30b and planar ground pattern 32.

L6 is the shortest distance from the periphery of conductive via 40 that interconnects signal lines 10 and 11 to the outer periphery of first signal line 10.

L7 is the shortest distance from the periphery of the above-described conductive via 40 to the outer periphery of second signal line 11.

L8 is the shortest distance from, among the plurality of conductive vias 41 provided in the first coplanar lines and excluding above-described conductive vias 41a, conductive via 41c that is closest to conductive via 40, to the outer periphery of planar ground pattern 30a on the first signal line 10 side.

When dimensions are set as described above, the range, in which the phases of each of the high-frequency currents that pass by the two current paths C and D shown in FIG. 3 does not invert at a particular signal wavelength λₒ (the minimum wavelength (maximum frequency) of the desired signal band), can be prescribed by:

$$\begin{matrix}[ Formula 5 ] & \\ [ \begin{matrix}\sqrt{{ɛ}_{1}} \times \{ \vert L 8 - L 1 \vert + dx \} + \sqrt{{ɛ}_{2}} \times \\ \{ \begin{matrix}dx + \vert L 3 - L 1 \vert + L 3 \times 2 + \\ L 5 + ( L 12 + φ / 2 ) \times 2\end{matrix} \}\end{matrix} ] - [ \begin{matrix}\sqrt{{ɛ}_{1}} \times ( L 6 + dx ) + \\ \sqrt{{ɛ}_{2}} \times ( L 5 + L 7 + dx )\end{matrix} ] < \frac{{λ}_{0}}{2} & ( 5 )\end{matrix}$$

or in other words, can be prescribed by:

\sqrt{∈₁}×(|L8−L1|−L6)+\sqrt{∈₂}×{|L3−L1|+2×L3−L7+2×(L12+φ/2)}<λ₀/2 [Formula 6]

Here, ∈₁ represents the effective relative dielectric constant of the first coplanar lines, ∈₂ represents the effective relative dielectric constant of the second coplanar lines, and φ represents the diameter of conductive vias 41.

In addition, the adoption of a configuration in which conductive vias 41a and planar ground pattern 32 of the second coplanar lines are separated means that Formula (2) must again be satisfied with respect to the outer periphery of planar ground pattern 32 on the first coplanar line side.

Based on FIGS. 2B and 4, the maximum distance R in this case is:

[Formula 7]

R=\sqrt{(L3+φ/2)²+(L12+φ/2)²}−φ/2 (6)

and based on Formulas (2) and (6),

[Formula 8]

\sqrt{∈₂}×{\sqrt{(L3+φ/2)²+(L12+φ/2)²}−φ/2+L5}<λ₀/4 (7)

whereby conductive via 41a in the vicinity of the connection portion of first signal line 10 and second signal line 11 is preferably separated from planar ground pattern 32 of the second coplanar lines such that these Formulas (5) and (7) are satisfied in the present embodiment.

The reflection characteristics realized by this embodiment are next described.

The following numerical conditions were adopted when examining the reflection characteristics. A three-layer wiring board composed of LTCC (low-temperature co-fired ceramic) board having a relative dielectric constant of 7.1 was used for dielectric substrate 20. First and second dielectric layers 20a and 20b of this dielectric substrate 20 were of the same material, the dielectric layer thickness L5 of each being 250 μm and the conductor thickness being 15 μm. In addition, the signal width of first signal line 10 was 150 μm, the gap spacing between first signal line 10 and planar ground pattern 30a was 66 μm, the signal line width of second signal line 11 was 100 μm, the gap spacing between second signal line 11 and planar ground pattern 32 was 120 μm, the diameter of conductive via 40 was 100 μm, the diameter 4 of conductive vias 41 was 150 μm, and all of the spacing of vias along the direction of signal transmission of the plurality of conductive vias 41 was 500 μm. In addition, the shortest distance L1 from the periphery of conductive via 41a to the outer periphery of planar ground pattern 30a on the first signal line 10 side was 85 μm. The shortest distance L8 from the periphery of conductive via 41c to the outer periphery of planar ground pattern 30a on the first signal line side was 144 μm. The shortest distance L3 from the periphery of conductive via 41b to the outer periphery of planar ground pattern 32 on the second signal line 11 side was 115 μm.

Relating to the configuration realized by these numerical conditions, a case is considered in which conductive vias 41a and planar ground pattern 32 are separated with 175 μm being the shortest distance from the periphery of conductive vias 41a in the vicinity of the connection portion of first signal line 10 and second signal line 11 to the outer periphery of planar ground pattern 32 of the second coplanar lines.

In this case, the shortest distance L12 from the periphery of conductive via 41b to the outer periphery of planar ground pattern 32 of the second coplanar lines on the first coplanar line side is 175 μm, the shortest distance L6 from the periphery of conductive via 40 to the outer periphery of first signal line 10 is 25 μm, and the shortest distance L7 from the periphery of conductive via 40 to the outer periphery of second signal line 11 is 0 μm. In addition, the effective relative dielectric constant ∈₁ of the first coplanar lines is 3.723, and the effective relative dielectric constant ∈₂ of the second coplanar lines is 7.1.

When the above-described numerical conditions are inserted in the aforementioned Formula (5), the left side is:

\sqrt{3.723}×(|144−85|−25)+\sqrt{7.1}×{|115−85|+2×115−0+2×(175+150/2)}=2091 μm[Formula 9]

Similarly, when the numerical conditions are inserted into the above Formula (7), the left side is:

\sqrt{7.1}×{\sqrt{(115+150/2)²+(175+150/2)²}−150/2+250}=1303 μm [Formula 10]

As a result, conductive vias 41a in the vicinity of the connection portion of first signal line 10 and second signal line 11 and planar ground pattern 32 of the second coplanar lines are separated such that 2091 μm<λ₀/2, and moreover, such that 1303 μm<λ₀/4, i.e., 5212 μm<λ₀ are satisfied in the present embodiment.

The frequency can be derived by means of the following formula (8).

c=f·λ₀, i.e., f=c/λ₀ (8)

where c represents the speed of light, or 3.0×10⁸ m/s, and f represents the frequency.

Considering a case in which the left side and right side are equal in the relational expression 5212 μm<λ₀ and assuming that λ₀=5212×10⁻⁸, f=58×10⁹ Hz=58 GHz is calculated from the above Formula (8).

In other words, in the case of a separation width of 175 μm, the frequency range that satisfies 5212 μm<λ₀ is lower than 58 GHz, and up to the level of 58 GHz, a separation width is set that enables an improvement of the reflection characteristics.

When the values φ=150 μm, L3=115 μm, L5=250 μm, ∈₂=7.1, and λ₀=5450 μm (f=55 GHz) are substituted in the above-described formula (4), the spacing dx of the plurality of conductive vias 41 that are formed in the second coplanar lines must satisfy the range dx<556 μm. However, because 500 μm is a reasonable value in the design for the via spacing dx along the direction of signal transmission of the plurality of conductive vias 41, dx=500 μm in the analysis of the embodiment.

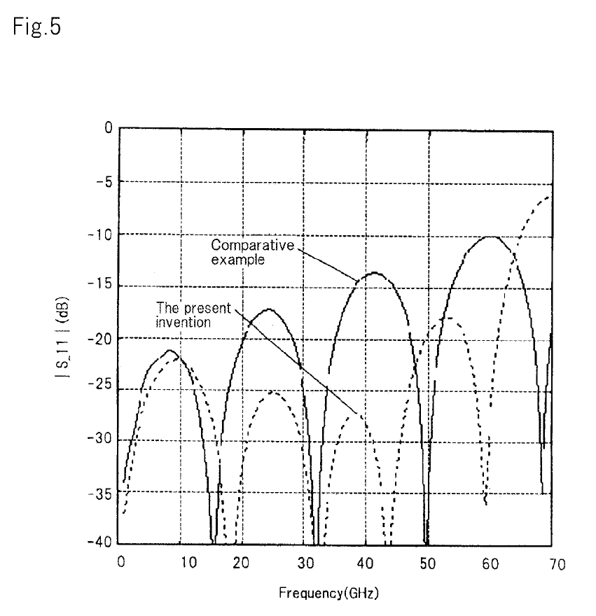

A comparative example in which conductive vias 41a in the vicinity of the connection portion of first signal line 10 and second signal line 11 are not separated from planar ground pattern 32 of the second coplanar lines and the present embodiment in which conductive vias 41a and planar ground pattern 32 are separated with a shortest distance of 175 μm from the periphery of conductive vias 41a to the outer periphery of planar ground pattern 32 of the second coplanar lines were constructed with the above-described numerical conditions and a comparison of input reflection characteristics was then carried out. FIG. 5 shows the results of the electromagnetic field analysis.

As can be understood from this figure, the effect of improving the reflection characteristic is obtained by the present embodiment, the frequency range in which the reflection characteristic is no greater than −20 dB extending over a broad band from a low frequency band to 49 GHz, and the frequency range in which the reflection characteristic is no greater than −15 dB likewise extending over a broad band from a low frequency band to 62 GHz.

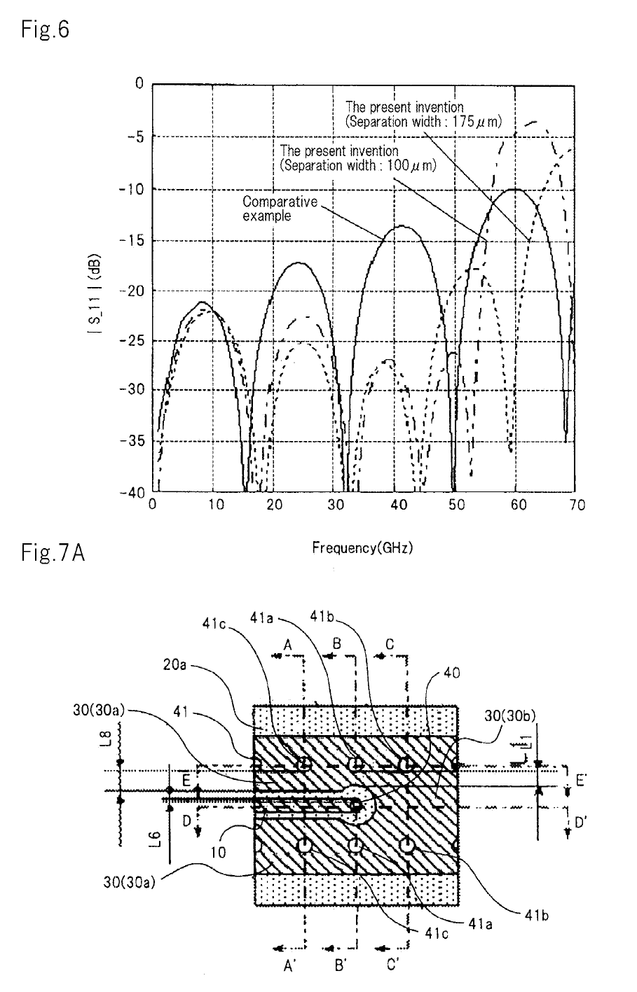

FIG. 6 further shows the results of electromagnetic field analysis when the above-described separation width is varied in the present embodiment. As can be seen from this figure, as the separation width increases, improvement of the reflection characteristics is exhibited over a broader band. In other words, the frequency range in which the S parameter |S_11| that represents the degree of reflection is no greater than −15 dB extends from the low frequency band to 38 GHz in the comparative example. In contrast, when the separation width between conductive via 41a and ground pattern 50 is made 100 μm, the frequency range extends from the low-frequency band to 55 GHz for an increase of approximately 17 GHz over the comparative example. In addition, when the separation width between conductive via 41a and ground pattern 50 is set to 175 μm, the frequency range extends from a low-frequency band to 62 GHz for an increase of approximately 24 GHz over the comparative example.

The technical idea of the first embodiment described hereinabove can also be reflected in the following embodiments.

### Second Embodiment

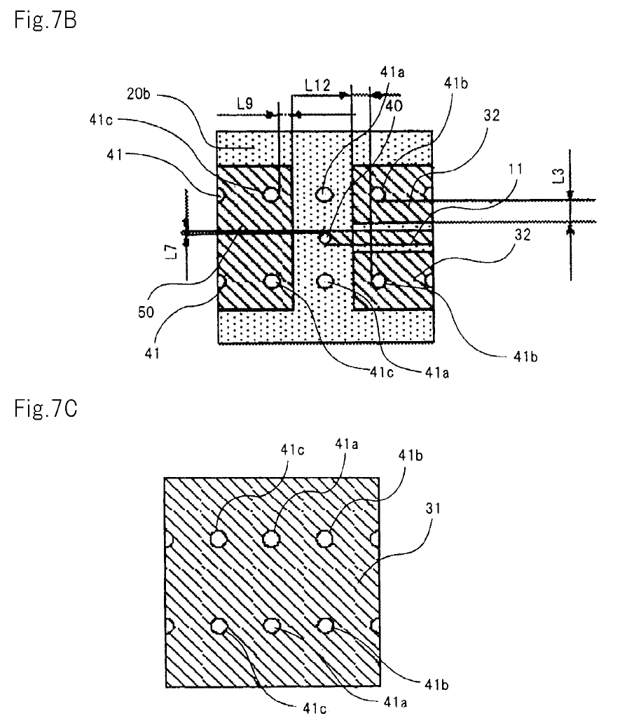

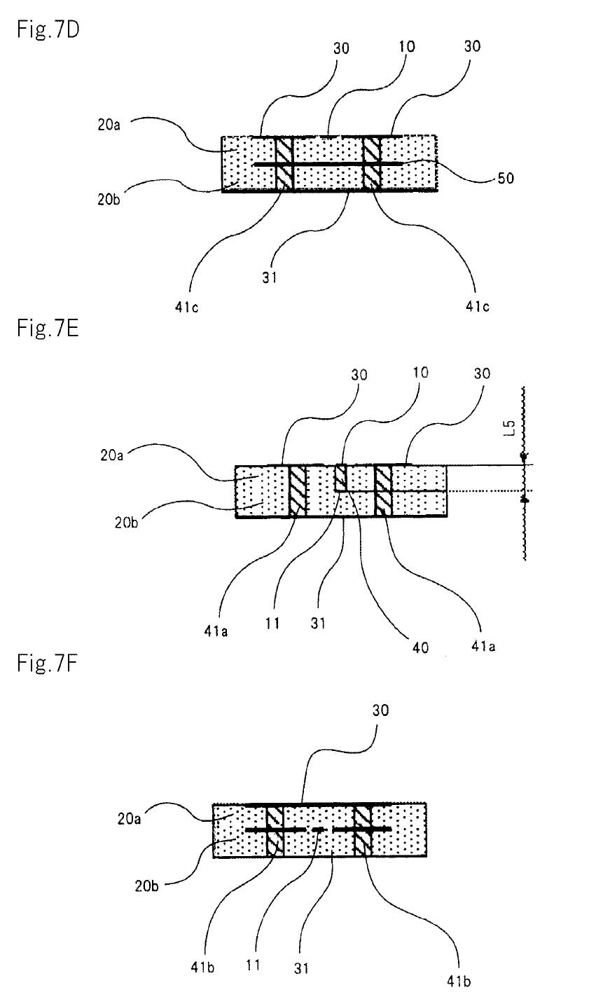

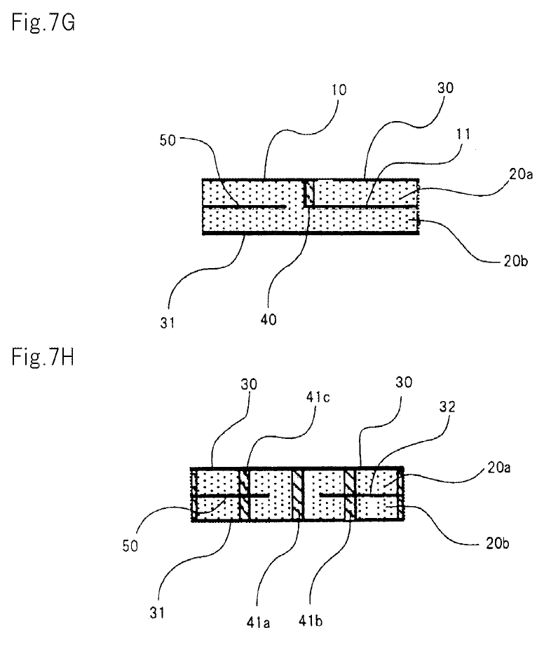

FIGS. 7A-7H show a configuration of the high-frequency wiring board according to the second embodiment of the present invention. To state in greater detail, FIG. 7A is a plan view showing the first wiring layer of the high-frequency wiring board of the present embodiment, FIG. 7B is a plan view of the second wiring layer, and FIG. 7C is a plan view of the third wiring layer. FIG. 7D is a sectional view of the board taken along line A-A′ of FIG. 7A, FIG. 7E is a sectional view of the board taken along line B-B′ of FIG. 7A, FIG. 7F is a sectional view of the board taken along line C-C′ of FIG. 7A, FIG. 7G is a sectional view of the board taken along line D-D′ of FIG. 7A, and FIG. 7H is a sectional view of the board taken along line E-E′ of FIG. 7A. In each of the figures, the same reference numbers are used for functional parts that are the same as constituent elements shown in FIGS. 1A-1D.

The high-frequency wiring board of the present embodiment is made up of dielectric substrate 20 realized by stacking two dielectric layers 20a and 20b. First coplanar lines are formed on the upper surface of first dielectric layer 20a, which is the obverse surface (first wiring layer) of dielectric substrate 20 (FIG. 7A). These first coplanar lines are made up from first signal line 10 and planar ground pattern 30a formed on both sides of first signal line 10 and on the same layer as first signal line 10. In addition, second coplanar lines are formed on the upper surface of second dielectric layer 20b, which is an internal layer (second wiring layer) of dielectric substrate 20 (FIG. 7B). The second coplanar lines are made up from second signal line 11 and planar ground pattern 32 that is formed on both sides of second signal line 11 and on the same layer as second signal line 11. In addition, each of planar ground patterns 30a and 32 of the first and second coplanar lines, respectively, may also be formed on only one of the two side positions that sandwich each of the signal lines.

First signal line 10 of the first coplanar lines and second signal line 11 of the second coplanar lines that are on a different wiring layer than first signal line 10 are connected by conductive via 40 at the line end of each signal line.

First ground pattern 30b and second ground pattern 31 are formed on the first wiring layer and third wiring layer (the reverse surface of dielectric substrate 20) such that the layer on which second signal line 11 is formed is interposed from above and below. This second ground pattern 31 also extends into areas that are opposite the first coplanar lines and thus doubles as a lower-layer ground of the first coplanar lines.

First ground pattern 30b is connected to planar ground pattern 30a at the end in the first coplanar line direction and is thus unified as ground pattern 30.

In addition, planar ground pattern 30a of the first coplanar lines and second ground pattern 31 that doubles as the lower-layer ground of the first coplanar lines are interconnected by a plurality of conductive vias 41 arranged at a predetermined spacing along the direction of signal transmission of the first coplanar lines.

In addition, first ground pattern 30b that is on the upper layer of the second coplanar lines, planar ground pattern 32 of the second coplanar lines, and second ground pattern 31 are interconnected by the plurality of conductive vias 41 (41b) that are arranged at a predetermined spacing along the direction of signal transmission of the second coplanar lines.

Of the plurality of conductive vias 41, conductive vias 41a in the vicinity of the connection portion of first signal line 10 and second signal line 11 are separated from planar ground pattern 32 without interconnecting planar ground pattern 30a of the first coplanar lines and planar ground pattern 32 of the second coplanar lines as in the background art. More specifically, conductive vias 41a in the vicinity of the connection portion of first signal line 10 and second signal line 11 and planar ground pattern 32 of the second coplanar lines are separated by way of a predetermined width (dielectric width) in the direction in which the second coplanar lines extend from the vicinity of the connection portion of first signal line 11 and conductive via 40.

The configuration described above is the same as the first embodiment, but the following modifications are added to the first embodiment in the present embodiment. Specifically, ground pattern 50 is provided in the area that is opposite the first coplanar lines that are provided with planar ground pattern 30a and first signal line 10, and moreover, ground pattern 50 is provided on the same layer as planar ground pattern 32 of the second coplanar lines. This ground pattern 50 is electrically connected to both planar ground pattern 30a of the first coplanar lines and second ground pattern 31 by a plurality of conductive vias 41 that are arranged at a predetermined spacing along the direction of signal transmission.

This ground pattern 50 is separated from ground pattern 32 without doubling as a planar ground pattern of the second coplanar lines as in the background art. More specifically, conductive vias 41a in the vicinity of the connection portion of first signal line 10 and second signal line 11 and ground pattern 50 of the lower layer of the first coplanar lines are separated by way of a predetermined width (dielectric width) in the direction in which the first coplanar lines extend from the vicinity of the connection portion of the second signal line 11 and conductive via 40.

In the high-frequency transmission lines of this type of high-frequency wiring board, conductive vias 41a in the vicinity of the connection portion of first signal line 10 and second signal line 11 and planar ground pattern 32 of the second coplanar lines are separated in the direction in which the second coplanar lines extend from the vicinity of the connection portion of first signal line 10 and conductive via 40.

As a result, when a signal is transmitted from the first coplanar lines to the second coplanar lines, the high-frequency current paths that are propagated in first ground pattern 30b of the upper layer of the second coplanar lines is limited to one. In other words, the high-frequency current path that is propagated in first ground pattern 30b during transmission of a signal to the second coplanar lines is the only path that passes directly from planar ground pattern 30a of the first coplanar lines to first ground pattern 30b. In this way, phase interference of the high-frequency current that is propagated in first ground pattern 30b does not occur, and as a result, the reflection characteristics that deteriorate with progress from low frequencies to high frequencies can be improved.

Still further, in the present embodiment, conductive vias 41a in the vicinity of the connection portion of first signal line 10 and second signal line 11 and ground pattern 50 of the lower layer of the first coplanar lines are separated by a predetermined width (dielectric width) in the direction in which the first coplanar lines extend from the vicinity of the connection portion of second signal line 11 and conductive via 40.

As a result, even supposing the transmission of a signal from the second coplanar lines to the first coplanar lines, the high-frequency current path that is propagated in ground pattern 50 of the lower layer of the first coplanar lines is limited to one. In other words, the high-frequency current path that is propagated in ground pattern 50 at the time of signal transmission to the first coplanar lines is the only path that passes from planar ground pattern 32 of the second coplanar lines and successively by way of conductive via 41b, first ground pattern 30b of the second coplanar lines, planar ground pattern 30a of the first coplanar lines, and conductive via 41c along the direction of signal transmission toward ground pattern 50. In this way, phase interference of the high-frequency current that is propagated in ground pattern 50 does not occur. As a result, reflection characteristics that progressively deteriorate with progress from low frequencies to high frequencies can be improved.

Essentially, according to the present embodiment, superior reflection characteristics can be maintained even when the direction of signal transmission between the first coplanar lines and second coplanar lines is altered according to the state of application of the high-frequency wiring board.

This type of effect is obtained if there is separation between conductive vias 41a in the vicinity of the connection portion of first signal line 10 and second signal line 11 and planar ground pattern 32 of the second coplanar lines in the direction in which of the second coplanar lines extend from the vicinity of the connection portion of first signal line 10 and conductive via 40, and further, between conductive vias 41a in the vicinity of the connection portion of first signal line 10 and second signal line 11 and ground pattern 50 of the lower layer of the first coplanar lines in the direction in which the first coplanar lines extend from the vicinity of the connection portion of second signal line 11 and conductive via 40, and these separation portions may take any form. The confronting sides that form the separation portions between conductive vias 41a and planar ground pattern 32 of the second coplanar lines and between conductive vias 41a and ground pattern 50 of the lower layer of the first coplanar lines need not be a straight line as shown in the figures and need not be formed perpendicular to the direction of signal transmission of first coplanar lines and second coplanar lines.

Additional conditions for further improving the reflection characteristics are next described. However, the following explanation presupposes a configuration in which conductive vias 41a and planar ground pattern 32 of the second coplanar lines, and further, conductive vias 41a and ground pattern 50 of the lower layer of the first coplanar lines are separated by the width of a fixed spacing.

As additional conditions for achieving a further improvement of reflection characteristics in the present embodiment, a first separation width between conductive vias 41a and planar ground pattern 32 of the second coplanar lines as well as a second separation width between conductive vias 41a and ground pattern 50 of the lower layer of the first coplanar lines are prescribed as described below.

The upper limit of the above-described first separation width is prescribed by the spacing of conductive vias 41 formed on the second coplanar lines (the arrangement spacing of conductive vias 41a and 41b), and the reason for this limit and a method for calculating the via spacing are as described in the first embodiment.

Regarding the above-described second separation width, the same thinking as for the method of prescribing the first separation width is adopted, the second separation width being prescribed by the spacing of conductive vias 41 formed on first coplanar lines (the arrangement spacing of conductive vias 41a and 41c). In other words, the second separation width is prescribed to be greater than 0, and moreover, to be no greater than the spacing from conductive vias 41a in the vicinity of connection end of second signal line 11 to the next conductive vias 41c in the direction of signal transmission. In addition, the arrangement spacing of, for example, conductive vias 41a and 41c that are formed in the first coplanar lines is a value determined for realizing the desired frequency band in the first coplanar lines. Although this value is not explained in detail, the value can be found using the same calculation method and concepts as explained in the first embodiment.

As in the first embodiment, the above-described first and second separation widths can also be prescribed as shown below. Specifically, during signal transmission from one group of coplanar lines to the other coplanar lines, conditions are preferable whereby the difference in the electrical path lengths (difference in electrical lengths converted by the effective relative dielectric constant) of the high-frequency current that is propagated through ground patterns and the high-frequency current that is propagated through signal lines do not greatly diverge, and the first and second separation widths are therefore prescribed within ranges in which the phases of the high-frequency currents on the ground pattern side and signal line side do not invert at a particular signal wavelength λ₀ (the minimum wavelength (maximum frequency) of the desired signal band). Because the method of prescribing the first separation width according to this concept was explained in the first embodiment, only the method of prescribing the second separation width is described here.

First, as shown in FIGS. 7A, 7B, and 7E, L1 is the shortest distance from the periphery of, among the plurality of conductive vias 41 provided in the first coplanar lines, conductive vias 41a that are closest to conductive via 40, to the periphery of planar ground pattern 30 on the first signal line 10 side.

L3 is the shortest distance from the periphery of, among the plurality of conductive vias 41 provided in the second coplanar lines and excluding previously described conductive vias 41a, conductive vias 41b that are closest to conductive via 40, to the periphery of planar ground pattern 32 on the second signal line 11 side.

L12 is the shortest distance from the periphery of the above-described conductive vias 41b to the periphery of planar ground pattern 32 on the first coplanar line side.

L5 is the dielectric layer thickness between first ground pattern 30b and planar ground pattern 32.

L6 is the shortest distance from the periphery of conductive via 40 that interconnects signal lines 10 and 11 to the periphery of first signal line 10.

L7 is the shortest distance from the periphery of the above-described conductive via 40 to the periphery of second signal line 11.

L8 is the shortest distance from the periphery of, among the plurality of conductive vias 41 provided in the first coplanar lines and excluding above-described conductive vias 41a, conductive vias 41c that are closest to conductive via 40, to the outer periphery of planar ground pattern 30a on the first signal line 10 side.

L9 is the shortest distance from the periphery of the above-described conductive vias 41c to the outer periphery of ground pattern 50 on the second coplanar line side.

Finally, dx is the spacing of conductive vias 41a and 41c.

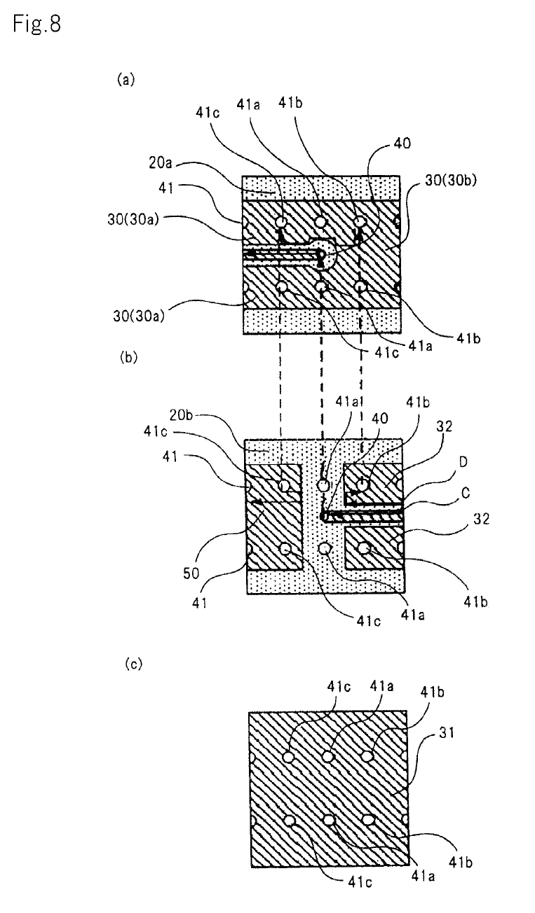

Referring to FIG. 8, when the above-described dimensions are set, the range in which inversion does not occur in the phases of each of the high-frequency currents that pass by way of high-frequency current path C on the signal line side that is propagated through signal lines 10 and 11 and high-frequency current path D on the ground pattern side that is propagated through ground pattern 50 from planar ground pattern 32 of the second coplanar lines and successively through conductive via 41b, first ground pattern 30b of the second coplanar lines, planar ground pattern 30a of the first coplanar lines, and conductive via 41c along the direction of signal transmission at a particular signal wavelength λ₀ (the minimum wavelength (maximum frequency) of the desired signal band) can be prescribed by the formula:

$$[ \begin{matrix}\sqrt{{ɛ}_{1}} \times \{ \begin{matrix}2 \times ( φ / 2 + L 9 ) + 2 \times \\ L 8 + L 5 + dx + \vert L 8 - L 11 \vert\end{matrix} \} + \\ \sqrt{{ɛ}_{2}} \times \{ \begin{matrix}\vert L 3 - L 1 \vert + dx + 2 \times \\ L 3 + L 5 + 2 \times ( φ / 2 + L 12 )\end{matrix} \}\end{matrix} ] - [ \begin{matrix}\sqrt{{ɛ}_{1}} \times ( dx + L 6 ) + \\ \sqrt{{ɛ}_{2}} \times ( L 5 + L 7 + dx )\end{matrix} ] < \frac{{λ}_{0}}{2} \qquad [ Formula 11 ]$$

this formula being equivalent to:

[Formula 12]

\sqrt{∈₁}×{|L8−L1|+L5−L6+2×L8+2×(φ/2+L9)}+\sqrt{∈₂}×{|L3−L1|2+L3+2×(φ/2+L12)−L7}<λ₀/2 (9)

As a result, in the present embodiment, conductive vias 41a and ground pattern 50 of the lower layer of the first coplanar lines are preferably separated such that Formula (9) is satisfied, and conductive vias 41a and planar ground pattern 32 of the second coplanar lines are preferably separated such that Formula (7) is satisfied.

Explanation next regards the reflection characteristics realized by the present embodiment.

In the examination of the reflection characteristics, the same numerical conditions were adopted as in the first embodiment with the exception of the following points of change. Specifically, because ground pattern 50 of the lower layer of the first coplanar lines is provided in the present embodiment, the first signal line width was changed to 130 μm and the gap spacing of first signal line 10 and planar ground pattern 30a was changed to 60 μm. Accompanying these alterations, shortest distance L8 from the periphery of conductive vias 41c to the outer periphery of planar ground pattern 30a on the first signal line 10 side becomes 160 μm.

In addition to the configuration realized by these numerical conditions, conductive vias 41a and planar ground pattern 32 are separated with 175 μm being the shortest distance from the periphery of conductive via 41a in the vicinity of connection portion of first signal line 10 and second signal line 11 to the outer periphery of planar ground pattern 32 of the second coplanar lines. A case is further considered in which conductive vias 41a and ground pattern 50 are separated with 175 μm being the shortest distance from the periphery of conductive via 41a to the outer periphery of ground pattern 50 of the lower layer of the first coplanar lines. In this case, shortest distance L12 from the periphery of conductive via 41b to the outer periphery of planar ground pattern 32 of the second coplanar lines on the first coplanar line side is 175 μm, shortest distance L6 from the periphery of conductive via 40 to the outer periphery of first signal line 10 is 25 μm, and shortest distance L7 from the periphery of conductive via 40 to the outer periphery of second signal line 11 is 0 μm. In addition, shortest distance L9 from the periphery of conductive via 41c to the outer periphery of ground pattern 50 on the second coplanar line side is 175 μm. Finally, the effective relative dielectric constant c of the first coplanar lines is 3.767, and the effective relative dielectric constant ∈₂ of the second coplanar lines is 7.1.

When these numerical conditions are substituted in Formula (7) that was explained in the first embodiment, the left side becomes:

[Formula 13]

\sqrt{7.1}×{\sqrt{(115+150/2)²+(175+150/2)²}−150/2+250}=1303 μm

As a result, in the present embodiment, conductive vias 41a and planar ground pattern 32 that are on the second wiring layer are separated such that 1303 μm<λ₀/4 is satisfied. Considering a case in which the left side and right side are equal in the relational expression 1303 μm<λ₀/4, if λ₀=4×1303×10⁻⁶, then f=58×10⁹ Hz=58 GHz is calculated by means of Formula (8) that was explained in the first embodiment. In other words, when the above-described first separation width is 175 μm, the frequency range that satisfies 5212 μm<λ₀ is less than 58 GHz, and a first separation width is set that enables an improvement of the reflection characteristics up to the level of 58 GHz.

When the above-described numerical conditions are further substituted in the above-described Formula (9) for prescribing the second separation width, the left side becomes:

\sqrt{3.767}×{|160−85|+250−25+2×160+2×(75+175)}+\sqrt{7.1}{|115−85|+2×115+2×(75+175)−0}4199 μm [Formula 14]

Thus, in the present embodiment, conductive vias 41a and planar ground pattern 32 on the second wiring layer, and further, conductive vias 41a and ground pattern 50 are separated such that 4199 μm<λ₀/2 is satisfied. Considering a case in which the left side and right side are equal in the relational expression 4199 μm<λ₀/2, if λ₀2=2×4199×10⁻⁶, f=36×10⁹ Hz=36 GHz is calculated from the above-described Formula (8). In other words, when the above-described first separation width is 175 μm, and moreover, when the second separation width is 175 μm, the frequency range that satisfies 4056 μm<λ₀/2 is less than 36 GHz, and the second separation width is set such that it enables an improvement of the reflection characteristics up to the level of 36 GHz.

In addition, a comparative example, that was described in the above-described first embodiment in which planar ground pattern 30a of the first coplanar lines and first ground pattern 30b of the upper layer of the second coplanar lines are not separated, and the present embodiment, were constructed by the above-described numerical conditions and a comparison of input reflection characteristics carried out. In the present embodiment that was compared, conductive vias 41a and ground pattern 32 as well as conductive vias 41a and ground pattern 50 are separated by slit-shaped separation widths of 175 μm as described above.

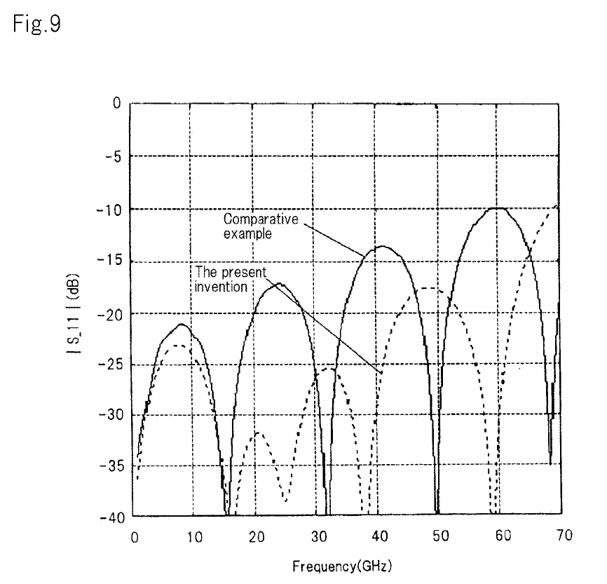

FIG. 9 shows the results of electromagnetic field analysis of these examples. As can be understood from this figure, an improvement in reflection characteristics is obtained by means of the present embodiment over a broad band, the frequency range in which the reflection characteristic was no greater than −20 dB ranging from a low frequency region to 43 GHz and the frequency range in which the reflection characteristic was no greater than −15 dB ranging from a low frequency region to 65 GHz.

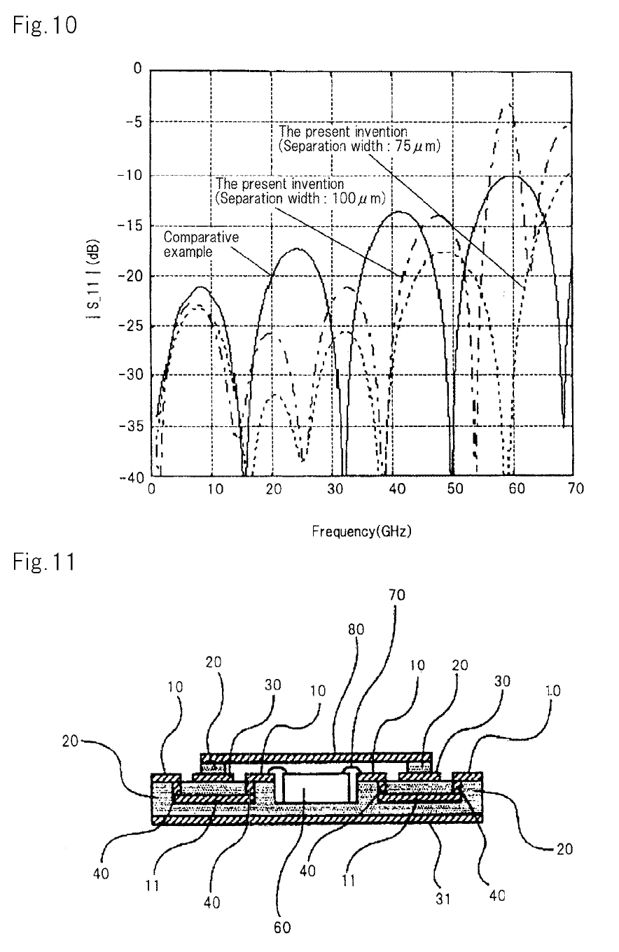

FIG. 10 shows the results of electromagnetic field analysis for a case in the present embodiment in which the separation width between conductive vias 41a and ground pattern 50 was varied. As can be understood from this figure, the greater the separation width, the broader the band over which the effect of improving reflection characteristics is exhibited.

Essentially, the frequency range in which the S parameter |S_11| that represents the degree of reflection in FIG. 9 is no greater than −20 dB extends from a low frequency region to approximately 20 GHz in the comparative example. In contrast, when the separation width between conductive vias 41a and ground pattern 50 is set to 100 μm, the frequency range extends from the low frequency region to approximately 42 GHz for an increase of approximately 22 GHz over the comparative example. In addition, when the separation width between conductive vias 41a and ground pattern 50 is 175 μm, the frequency range extends from the low frequency region to approximately 44 GHz for an increase of 24 GHz over the comparative example.

### Another Embodiment

In each of the above-described embodiments, conductive vias were used as the means for connecting different layers, but the present invention is not limited to this form and any electrical connection means having conductivity such as through-holes can be applied. In addition, although explanation regarded three-layer wiring boards, the present invention can be applied to multilayer wiring boards of three or more layers, and can further be applied in constructions in which first signal line 10 and ground patterns 30a and 30b are inside dielectric substrate 20.

In the figures showing each of the embodiments, first signal line 10 and second signal line 11 may diverge somewhat and need not lie along a straight line. In this case, moreover, the opposing sides that prescribe the separation width between conductive vias 41a and planar ground pattern 32 of the second coplanar lines or the opposing sides that prescribe the separation width between conductive vias 41a and ground pattern 50 of the lower layer of the first coplanar lines need not be formed perpendicular to the signal transmission direction.

The high-frequency wiring board of another embodiment has first coplanar lines and second coplanar lines formed on a different layer from the first coplanar lines, and is a wiring board in which the first coplanar lines and the second coplanar lines are each connected at respective line ends. In this high-frequency wiring board, there is only one path of high-frequency current that is propagated from the planar ground pattern of the first coplanar lines, in the vicinity of the connection portion of the line ends of the first coplanar lines and the second coplanar lines, to a ground pattern on the same layer as the planar ground pattern.

The high-frequency wiring board of this invention is provided with: the above-described first coplanar lines that are formed inside or on the obverse surface of a dielectric substrate; the above-described second coplanar lines formed on a different wiring layer than the first coplanar lines; and first conductive vias for connecting together each of the line ends of signal lines provided in these coplanar lines.

The above-described first coplanar lines are provided with a first signal line formed inside or on the obverse surface of a dielectric wiring layer and a first ground pattern arranged on the same surface and around the first signal line on the same wiring layer as the first signal line. The above-described second coplanar lines are provided with: the above-described first ground pattern, a second signal line that is formed on a different wiring layer than the first signal line, and a planar ground pattern formed on at least one of the two positions that sandwiches the second signal line on the same wiring layer as the second signal line. In addition, a second ground pattern is formed on the wiring layer on the opposite side of the first ground pattern with respect to the layer on which the second coplanar lines are formed.

A plurality of second conductive vias are arranged at a predetermined spacing along the direction of signal transmission that passes through the first and second coplanar lines, and these conductive vias include: conductive vias a for connecting first ground pattern of the first coplanar lines and the second ground pattern, and further, that are closest to the first conductive via; conductive vias b for connecting the first ground pattern and the planar ground pattern of the second coplanar lines; and conductive vias c for connecting the first ground pattern of the first coplanar lines and the second ground pattern.

In this invention, when a signal is being transmitted from the first coplanar lines to the second coplanar lines, the high-frequency current paths propagated in the first ground pattern of the upper layer of the second coplanar lines are limited to one. In other words, the high-frequency current path propagated in the first ground pattern at the time of signal transmission to the second coplanar lines is the only path that passes directly from the first ground pattern located on both sides that surround the first coplanar lines to the first ground pattern of the upper layer of the second coplanar lines without passing through different layers.

Because phase interference of the high-frequency current propagated in the first ground pattern is thus controlled, reflection characteristics that progressively deteriorate from low frequencies to high frequencies can be improved.

In addition, by reducing the difference between the phase of the high-frequency current that is propagated through the planar ground pattern of the second coplanar lines and the phase of the high-frequency current that is propagated through the signal lines, i.e., the difference in electrical lengths that are converted to wavelength, the reflection characteristics that progressively deteriorate from low frequencies to high frequencies can be more greatly improved.

The high-frequency wiring board of the present invention that is based on each of the embodiments can be applied as the wiring board of a high-frequency module that is incorporated in, for example, a portable telephone device, a PDA (Personal Digital Assistant) terminal, and many other electronic devices.

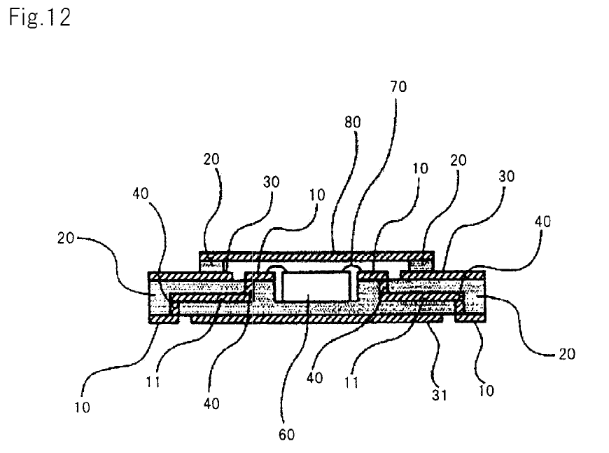

For example, high-frequency modules as shown in FIG. 11 and FIG. 12 are obtained by providing depressions in dielectric substrate 20, accommodating LSI chip 60 that is an electronic device that operates by a clock signal, then electrically connecting the LSI chip to first signal lines 10 of first coplanar lines that are formed on the obverse surface of dielectric substrate 20 with bonding wires 70, and then covering LSI chip 60 by cover 80. FIG. 11 shows a configuration in which first signal lines 10 of the first coplanar lines that are connected to LSI chip 60 and first signal lines 10 of the other first coplanar lines that are formed on the same obverse surface of dielectric substrate 20 are connected by way of second signal lines 11 of second coplanar lines that are formed inside dielectric substrate 20. Alternatively, FIG. 12 shows a configuration in which first signal lines 10 of first coplanar lines that are connected to LSI chip 60 are connected to first signal lines 10 of other first coplanar lines that are formed on the reverse surface of dielectric substrate 20 by way of second signal lines 11 of second coplanar lines that are formed inside dielectric substrate 20.

In either configuration, the configuration is characterized by the separation of conductive vias 41a (not shown) from planar ground pattern 32 of the second coplanar lines or from ground pattern 50 of the lower layer of the first coplanar lines in the wiring direction from first coplanar lines to second coplanar lines that are connected by conductive vias 40. Although LSI chip 60 is embedded in a high-frequency wiring board in the forms shown in FIG. 11 and FIG. 12, the high-frequency module of the present invention is not limited to this form. Accordingly, the LSI chip may be surface-mounted to the wiring board by the flip-chip connection method or by the wire-bonding method depending on the application. Still further, a form is also possible in which LSI chip 60 is sealed by molded resin without using cover 80.

Although the high-frequency wiring board of the present invention and the high-frequency module that employs this high-frequency wiring board were described by showing a number of embodiments as described hereinabove, the invention of the present application is not limited to these embodiments and is obviously open to various modifications within a range that does not depart from the spirit of the invention.

This application claims priority based on Japanese Patent Application 2007-277686 for which application was submitted on Oct. 25, 2007 and incorporates all of the disclosures of that application.

1-10. (canceled)

11. A high-frequency wiring board comprising:
first coplanar lines provided with a first signal line and a first planar ground pattern formed on the same wiring layer as the first signal line; and
second coplanar lines provided with a second signal line formed on a wiring layer that differs from that of said first signal line, a second planar ground pattern formed on the same wiring layer as the second signal line, and a first ground pattern formed on the same wiring layer as said first coplanar lines;
wherein said first coplanar lines and said second coplanar lines are connected, and the end of said first planar ground pattern and the end of said first ground pattern are connected and unified; and
wherein said second planar ground pattern is formed at locations that do not overlap with the projected region of said first planar ground pattern when the region of said first planar ground pattern is projected perpendicularly onto the same wiring layer as said second signal line.

12. A high-frequency wiring board comprising:
first coplanar lines provided with a first signal line and a first planar ground pattern formed on the same wiring layer as the first signal line; and
second coplanar lines provided with a second signal line formed on a wiring layer that differs from said first signal line, a second planar ground pattern formed on the same wiring layer as the second signal line, and a first ground pattern formed on the same wiring layer as said first coplanar lines;
wherein said first coplanar lines and said second coplanar lines are connected such that a signal is transmitted from said first coplanar lines to said second coplanar lines and the end of said first planar ground pattern and the end of said first ground pattern are connected and unified; and
wherein, when a signal is being transmitted from said first coplanar lines to said second coplanar lines, the path of high-frequency current that is propagated from said first planar ground pattern to said first ground pattern includes points that pass only by way of the connection at the end of said first planar ground pattern and the end of said first ground pattern that are formed on the same layer.

13. The high-frequency wiring board as set forth in claim 11, wherein:
said first signal line in said first coplanar lines is formed inside or on the obverse surface of a dielectric substrate, and said first planar ground pattern is formed on at least one of two side positions that sandwich said first signal line on the same wiring layer as the first signal line; and
said second planar ground pattern on said second coplanar lines is formed on at least one of two side positions that sandwich said second signal line on the same wiring layer as said second signal line.

14. The high-frequency wiring board as set forth in claim 13, comprising:
a first conductive via for connecting said first signal line and said second signal line at the line end of each signal line;
a second ground pattern that is formed on, with respect to the wiring layer on which said second coplanar lines are formed, the wiring layer that is opposite the layer of said first ground pattern; and
a plurality of second conductive vias that are arranged at a predetermined spacing along the direction of signal transmission that passes through said first and second coplanar lines, these second conductive vias including: conductive vias a that are closest to said first conductive via among conductive vias that connect said first planar ground pattern and said second ground pattern, conductive vias b for connecting said first ground pattern and said second planar ground pattern, and conductive vias c for connecting said first planar ground pattern and said second ground pattern;
wherein said second planar ground pattern is separated from said conductive vias a in the direction in which said second coplanar lines extend from the vicinity of the connection portion of said first signal line and said first conductive via.

15. The high-frequency wiring board as set forth in claim 14, wherein the shortest distance between said second planar ground pattern and the periphery of said conductive vias a is no greater than the spacing between said second conductive vias set on said second coplanar lines.

16. The high-frequency wiring board as set forth in claim 14, wherein when:
L1 is the shortest distance from the periphery of, among the plurality of said second conductive vias provided in said first coplanar lines, said conductive via a that is closest to said first conductive via that connects said first signal line and said second signal line at the line end of each signal line, to the outer periphery of said first signal line side of said first planar ground pattern;
L3 is the shortest distance from the periphery of, among the plurality of said second conductive vias provided on said second coplanar lines and excluding said conductive vias a, said conductive via b that is closest to said first conductive via, to the outer periphery of said second signal line side of said second planar ground pattern;
L5 is the dielectric layer thickness between said first ground pattern and said second planar ground pattern;
L6 is the shortest distance from the periphery of said first conductive via to the outer periphery of said first signal line;
L7 is the shortest distance from the periphery of said first conductive via to the outer periphery of said second signal line;
L8 is the shortest distance from the periphery of, among the plurality of said second conductive vias provided in said first coplanar lines and excluding said conductive vias a, said conductive via c that is closest to said first conductive via, to the outer periphery of said first signal line side of said first planar ground pattern;
L12 is the shortest distance from the periphery of said conductive via b to the outer periphery of said first coplanar line side of said second planar ground pattern;
∈₁ is the effective relative dielectric constant of said first coplanar lines;
∈₂ is the effective relative dielectric constant of said second coplanar lines;
φ is the diameter of said second conductive vias; and
λ₀ is the minimum wavelength in a vacuum in the signal band that is transmitted;
said second planar ground pattern and said conductive vias a are separated such that the following relational expressions are satisfied:
\sqrt{∈₁}×(|L8−L1|−L6)+\sqrt{∈₂}×{L3−L1|+2×L3−L7+2×(L12+φ/2)}<λ₀/2 [Formula 1]
and
\sqrt{∈₂}×{\sqrt{(L3+φ/2)²+(L12+φ/2)²}−φ/2+L5}<λ₀/4 [Formula 2]

17. The high-frequency wiring board as set forth in claim 14, further comprising:
a third ground pattern formed in an area of the same wiring layer as said second coplanar lines that are opposite the area in which said first coplanar lines are formed and electrically connected to both said first planar ground pattern and said second ground pattern by said second conductive vias;
wherein said third ground pattern is separated from said conductive vias a in the direction in which said first coplanar lines extend from the vicinity of the connection portion of said second signal line and said first conductive via.

18. The high-frequency wiring board as set forth in claim 17, wherein the minimum distance between the separated third ground pattern and the peripheries of said conductive vias a is no greater than the spacing of said second conductive vias that is set in said first coplanar lines.

19. The high-frequency wiring board as set forth in claim 17, wherein, when:
L9 is the shortest distance from the periphery of said conductive via c to the outer periphery of said second coplanar line side of said third ground pattern, and when
λ₀ is the minimum wavelength in a vacuum of the signal band that is transmitted,
the separation between said third ground pattern and said conductive vias a and the separation between said second planar ground pattern and said conductive vias a satisfy the following equation:
\sqrt{∈₁}×{|L8−L1|+L5−L6+2×L8+2×(φ/2+L9)}+\sqrt{∈₂}×{|L3−L1|+2×L3+2×(φ/2+L12)−L7}<λ₀/2 [Formula 3]

20. A high-frequency module wherein a semiconductor integrated circuit chip is mounted on the high-frequency wiring board as set forth in claim 11.
